(19) United States
(12) Patent Application Publication
(10) Pub. No.: US 2017/0194181 A1
(43) Pub. Date: Jul. 6, 2017

(54) OVERHEAD TRAVELING VEHICLE, TRANSPORTATION SYSTEM WITH THE SAME, AND METHOD OF OPERATING THE SAME

(71) Applicant: Micron Technology, Inc., Boise, ID (US)

(72) Inventors: Tsan-I Chen, Taoyuan City (TW); Yu-Kun Chen, New Taipei City (TW)

(21) Appl. No.: 14/986,729

(22) Filed: Jan. 4, 2016

(51) Int. Cl. H01L 21/677; H01F 7/20; H01F 7/02; B66C 19/00; G05D 1/02

(52) U.S. Cl. CPC H01L 21/67724; B66C 19/00; G05D 1/021; H01F 7/0252; H01F 7/20; H01L 21/67733

(57) ABSTRACT

An overhead traveling vehicle configured to transport wafers includes a mobile drive unit configured to move along a predetermined route on one side of a ceiling and a hoist unit configured to move along the predetermined route according to a position of the mobile drive unit. The mobile drive unit and the hoist unit respectively include a first magnet and a second magnet so that the hoist unit may be hung on the ceiling by the magnetic force generated between the magnets.

### BACKGROUND OF THE INVENTION

1. Field of the Invention

The present invention relates generally to the field of an overhead transportation system utilized in semiconductor foundries, and more particularly to a structure of an overhead traveling vehicle, the transportation system with the overhead traveling vehicle, and a method of operating the overhead traveling vehicle.

2. Description of the Prior Art

With the continuous progress of the semiconductor industry, in the development and the design of ultra large scale integrated circuits (ULSI), the size of components have be reduced down to the nanometer degree in order to meet the requirements for designs of high density integrated circuits. Accordingly, there are hundreds of process steps for fabricating the required integrated circuits, such as etching, polishing, diffusion and deposition processes. That is to say, from the beginning to the end of the fabrication process, wafers in a same lot may be repeatedly transported from one tool to another tool for processing.

Please refer to FIG. 1. FIG. 1 illustrates conventional overhead rail-guided system utilized in a semiconductor foundry. Generally, wafers can be processed in a semiconductor foundry 10 equipped with various kinds of processing apparatus 12, such as photolithographic, etching, polishing, diffusion and deposition apparatus. During the fabricating processes, the wafers loaded in suitable containers, such as front open united pods (FOUPs) can be repeatedly transported between load ports 14 of the processing apparatus 12 by overhead traveling vehicles 18. It is, however, often time-consuming during the transportation since the overhead traveling vehicles 18 are confined to move along overhead tracks 16, such as moving along path 20 above the processing apparatus, no matter what the distance between these apparatus is.

FIG. 2 illustrates another conventional overhead rail-guided system utilized in a semiconductor foundry. Referring to FIG. 2, the positions of the processing apparatus may be rearranged occasionally due to process renewal. As a result, some of the processing apparatus, such as processing apparatus 12a, may be kept at their original sites, while some of the processing apparatus, such as processing apparatus 12b, may be introduced into the semiconductor foundry 10 or rearranged from their original sites. Besides, in order to let the FOUPs be successfully transported to the load ports 14a and 14b of the rearranged processing apparatus 12a and 12b, the overhead tracks 16a and 16b may also be added or moved from their original sites based on the locations of the rearranged load ports 14a and 14b. However, in a case where the overhead track 16b is configured to guide the overhead traveling vehicle to the locations over the load ports 14b, all of the processing apparatus 12b under the overhead track 16b has to be shut down for a long period of time even if only one of the processing apparatus 12b is introduced or rearranged. Accordingly, the production rate of the semiconductor devices is reduced due to the down time of these processing apparatus 12b. These side effects are unfavorable for the management of the production chain.

### SUMMARY OF THE INVENTION

To this end, an improved overhead traveling vehicle, a transportation system with the same, and a method of operating the same are disclosed in the present application.

In accordance with one embodiment of the present invention, an overhead traveling vehicle configured to transport wafers includes a mobile drive unit configured to move along a predetermined route on one side of a ceiling and a hoist unit configured to move along the predetermined route according to a position of the mobile drive unit. The mobile drive unit and the hoist unit respectively include a magnet so that the hoist unit may be hung on the ceiling by the magnetic force generated between the magnets.

In accordance with another embodiment of the present invention, a method for operating an overhead traveling vehicle includes the following steps: generating a predetermined route by a route planning module; transmitting information of the predetermined route to a mobile drive unit; moving the mobile drive unit along the predetermined route on one side of a ceiling; and concurrently moving a hoist unit along the predetermined route according to the position of the mobile drive unit during the step of moving the mobile drive unit. Since the mobile drive unit and the hoist unit respectively include a magnet, the hoist unit may be hung on the ceiling during its movement by the magnetic force between the magnets.

In accordance with still another embodiment of the present invention, a system for operating an overhead traveling vehicle includes means for generating a predetermined route, a means for transmitting information of the predetermined route; and at least an overhead traveling vehicle operable to receive the information of the predetermined route. The overhead traveling vehicle may further includes a mobile drive unit configured to move along the predetermined route on one side of a ceiling and a hoist unit configured to move along the predetermined route according to a position of the mobile drive unit. Since the mobile drive unit and the hoist unit respectively include a magnet, the hoist unit may be hung on the ceiling during its movement by the magnetic force between the magnets.

Since rails are not necessary components for the operation of the overhead traveling vehicles and overhead traveling vehicles are able to move on any part of the ceiling in the semiconductor foundry even though there are no rails being installed, technical advantages of certain embodiments of the present invention include transporting the overhead traveling vehicles in a more flexible and time-efficient way compared with conventional railed-guided system. Additionally, during the process of moving processing equipment into or out of the semiconductor foundry, there is no need to shut down any processing equipment adjacent to the processing equipment being newly introduced or to be removed. Accordingly, according to certain embodiments of the present invention, the production rate of the semiconductor devices is not significantly affected during the renewal process.

Other technical advantages of the present invention will be readily apparent to one skilled in the art from the following figures, descriptions, and claims. Moreover, while specific advantages have been enumerated above, various embodiments may include all, some, or none of the enumerated advantages.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

For more complete understanding of the present invention and its advantage, reference is now made to the following description, taken in conjunction with accompanying drawings, in which:

FIG. 1 illustrates conventional overhead rail-guided system utilized in a semiconductor foundry;

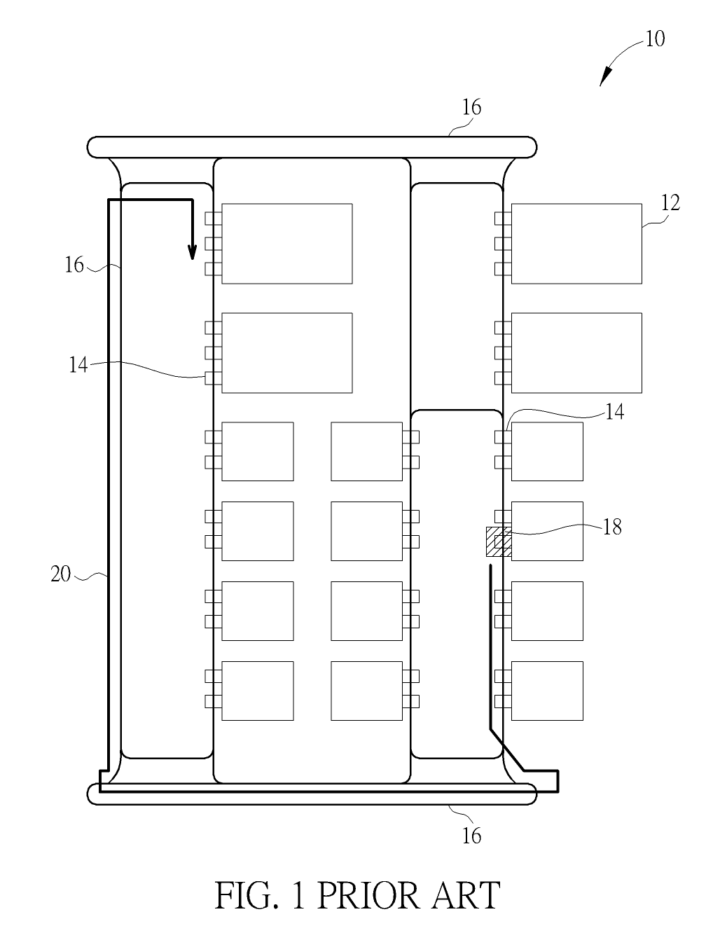

FIG. 2 illustrates another conventional overhead rail-guided system utilized in a semiconductor foundry;

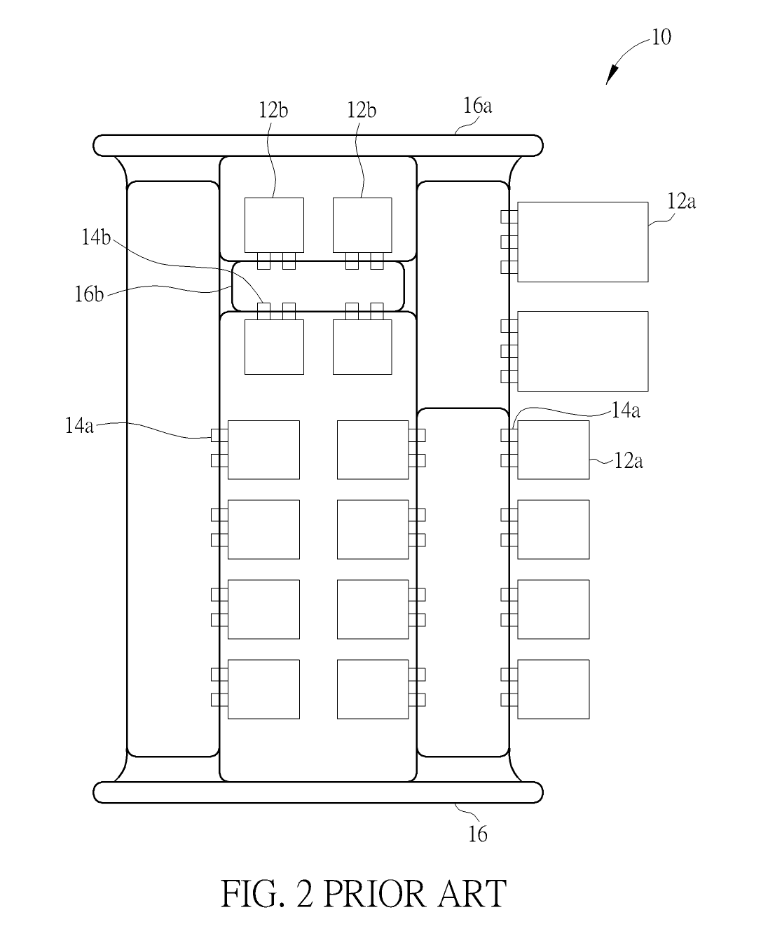

FIG. 3 illustrates in greater detail an exemplary overhead traveling vehicle utilized in a semiconductor foundry in accordance with one embodiment of the present invention;

FIG. 4 illustrates in greater detail an exemplary magnetic field generation unit installed in an overhead traveling vehicle in accordance with one embodiment of the present invention;

FIG. 5 illustrates an exemplary operation of an overhead traveling vehicle while lifting or lowering a container configured to be loaded with wafers in accordance with one embodiment of the present invention;

FIG. 6 illustrates in great detail the components of an exemplary management module that may be utilized to control the movement of an overhead traveling vehicle in accordance with one embodiment of the present invention;

FIG. 7 illustrates an exemplary operation of an overhead traveling vehicle while transporting a container configured to be loaded with wafers in accordance with one embodiment of the present invention; and

FIG. 8 is a flowchart detailing an exemplary operation of a management module in managing the movement of an overhead traveling vehicle in accordance with one embodiment of the present invention.

### DETAILED DESCRIPTION

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of components and regions may be exaggerated for clarity unless express so defined herein.

It will be understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

The terminology used herein is for the purpose of describing particular embodiments only and is not intended to be limiting. As used herein, the singular terms “a”, “an,” and “the” may be intended to include the plural forms as well, unless the context clearly indicates otherwise. The terms “comprises,” “comprising,” “includes” and/or “including” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the following paragraphs, the structure of an overhead traveling vehicle, a transportation system with the overhead traveling vehicle, and a method of operating the overhead traveling vehicle are disclosed in detail.

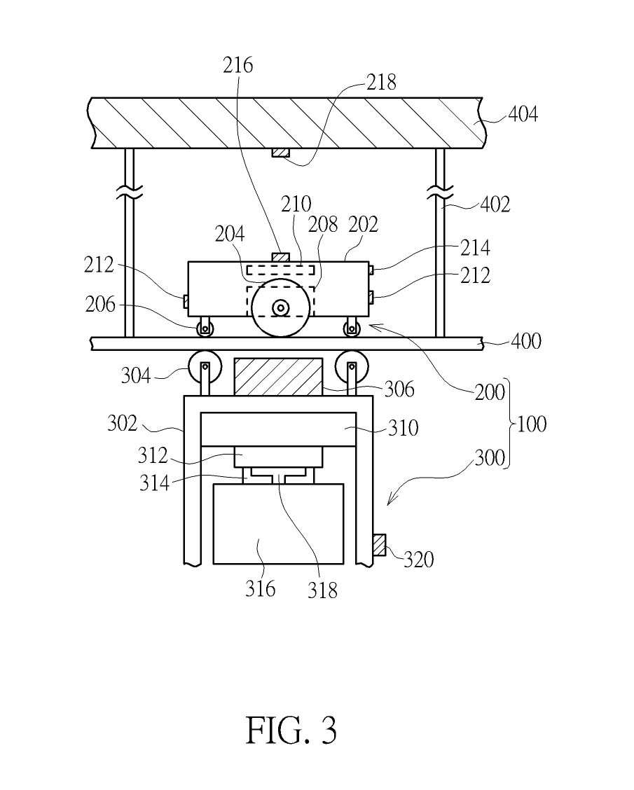

FIG. 3 illustrates in greater detail an exemplary overhead traveling vehicle utilized in a semiconductor foundry in accordance with one embodiment of the present invention. Referring to FIG. 3, an overhead traveling vehicle 100 moving on a platform 400 is utilized in a semiconductor foundry, which is configured to transport a container, such as a front opening unified pod (FOUP), from one place to another. In accordance of embodiments of the present invention, the overhead traveling vehicle 100 is an automated guided vehicle (AGV) capable of moving over the processing apparatus without rails. Accordingly, compared with an overhead vehicle utilized in conventional overhead rail-guided transportation system, the overhead traveling vehicle 100 disclosed herein can navigate the platform 400 more freely. Specifically, the platform 400 is hung on the ceiling 404 by a plurality of support columns 402. Each of the support columns 402 may consist of a rigid column or a retractable column so that the height between the platform 400 and the ceiling 404 can be defined by the length of the support column 402. In order to let the overhead traveling vehicle 100 move in the space freely, the length of the support column 402 must be long enough, and preferably longer than the height of an upper part of the overhead traveling vehicle 100.

Specifically, the components of the overhead traveling vehicle 100 may include at least a mobile drive unit 200 and a hoist unit 300. The mobile drive unit 200 and the hoist unit 300 may be respectively installed with magnets, such as a magnetic field generation unit 208 and 306, capable of generating a magnetic field in a normal or a particular situation. In other words, the magnetic field generation unit 208 and 306 may be permanent magnets or temporary magnets, such as electromagnets. By properly controlling the magnetic field, the magnetic force created by the magnetic field can be employed to hold the hoist unit 300 on the platform 400 during the operation of the hoist unit 300.

The mobile drive unit 200 is operable to move along a predetermined route on an upper side of a platform 400. The components of the mobile drive unit 200 in accordance of one embodiment of the present invention may include a body 202, at least a pair of motorized wheels 204 pivotally connected to the body 202, at least a pair of optional stabilizing wheels 206 positioned at the ends of the body 202, a magnetic field generation unit 208 installed at the lower portion of the body 202, and a control module 210 configured to monitor and/or control the operation of the mobile drive unit 200 as well as the overhead traveling vehicle 100. In addition, the mobile drive unit 200 further includes different kinds of sensors, such as location sensors 216 and obstacle sensors 212, installed on the body 202, and these sensors can be used to determine the location of the mobile drive unit 200 and detect obstacles near the mobile drive unit 200.

The motorized wheels 204 can be used to propel the mobile drive unit 200. For instance, in the illustrated embodiment, motorized wheels 204 are operable to rotate in a first direction to propel mobile drive unit 200 in a forward direction. The motorized wheels 204 are also operable to rotate in a second direction to propel mobile drive unit 200 in a backward direction. In the illustrated embodiment, the mobile drive unit 200 can be rotated by rotating motorized wheels 204 indifferent directions from one another or by rotating motorized wheels 204 at different speeds from one another.

The location sensor 216, in the illustrated embodiment, represents one or more sensors, detectors, or other components suitable for determining the location of mobile drive unit 200 in any appropriate manner. For example, in one particular embodiment, the workplace associated with the transportation system includes a number of fiducial marks 218 that mark points on a two-dimensional grid that covers all or a portion of workplace. In such embodiments, location sensor 216 may include a camera and suitable image- and/or video-processing components, such as an appropriately-programmed digital signal processor, to allow location sensor 216 to detect fiducial marks 218 within the camera's field of view. The control module 210 may store location information that location sensor 216 updates as location sensor 216 detects fiducial marks 218. As a result, the location sensor 216 may utilize fiducial marks 218 to maintain an accurate indication of the location mobile drive unit 200 and to aid in navigation when moving within workplace.

The obstacle sensor 212 represents one or more sensors capable of detecting objects located in one or more different directions in which mobile drive unit 200 is capable of moving. The obstacle sensor 212 may utilize any appropriate components and techniques, including optical, radar, sonar, pressure-sensing and/or other types of detection devices appropriate to detect objects located in the direction of travel of mobile drive unit 200. In particular embodiments, the obstacle sensor 212 may transmit information describing objects it detects to control module 210 so as to be used by the control module 210 to identify obstacles and to take appropriate remedial actions to prevent mobile drive unit 200 from colliding with obstacles and/or other objects.

The obstacle sensor 212 may also detect signals transmitted by other mobile drive units 200 operating in the vicinity of the illustrated mobile drive unit 200. For example, in particular embodiments of the transportation system, one or more mobile drive units 2000 may include an identification signal transmitter 214 that transmits a drive identification signal. The drive identification signal indicates to other mobile drive units 2000 that the object transmitting the drive identification signal is in fact a mobile drive unit 200. Identification signal transmitter 214 may be capable of transmitting infrared, ultraviolet, audio, visible light, radio, and/or other suitable signals that indicate to recipients that the transmitting device is the mobile drive unit 200.

Additionally, in particular embodiments, the obstacle sensor 212 may also be capable of detecting state information transmitted by other mobile drive units 200. For example, in particular embodiments, the identification signal transmitter 214 may be capable of including state information relating to mobile drive unit 200 in the transmitted identification signal. This state information may include, but is not limited to, the position, velocity, direction, and the braking capabilities of the transmitting mobile drive unit 200. In particular embodiments, mobile drive unit 200 may use the state information transmitted by other mobile drive units to avoid collisions when operating in close proximity with those other mobile drive units.

The control module 210 installed in the mobile drive unit 200 may be operable to monitor and/or control the operation of the motorized wheels 204. The control module 210 may also receive information from sensors such as the location sensor 216 and the obstacle sensors 212, and adjust the operation of drive module 120 and/or other components of mobile drive unit 200 based on this information. Additionally, in particular embodiments, mobile drive unit 200 may be configured to communicate with a management device of transportation system, and the control module 210 may receive commands transmitted to mobile drive unit 200 and communicate information back to the management device utilizing appropriate communication components of mobile drive unit 200. The control module 210 may include any appropriate hardware and/or software suitable to provide the described functionality. In particular embodiments, the control module 210 includes a general-purpose microprocessor programmed to provide the described functionality.

The overhead traveling vehicle 100 may also include the hoist unit 300 in addition to the mobile drive unit 200 disclosed above. The hoist unit 300 is operable to move on another side of the platform 400 and along the route that the mobile drive unit 200 moves along. Specifically, although the hoist unit 300 and the corresponding mobile drive unit 200 are separated by the platform 400, the hoist unit 300 can still be hung on the platform 400 during its movement. The reason is that the magnetic field generation units 306 and 208 are respectively installed in the hoist unit 300 and the mobile drive unit 200, and the magnetic field generation units 306 and 208 are able to create enough magnetic force to hold the hoist unit 300.

The hoist unit 300 in accordance with one embodiment of the structure shown in FIG. 3 may include at least a body 302 to which the magnetic field generation units 306 can be attached, a pair of auxiliary wheels 304 connected to the body 302, a location sensor 320 configured to detect the location of processing apparatus under the hoist unit 300, and a hoist 310 which lifts and lowers an elevation platform 312. During the transportation, a chuck 314 attached to the elevation platform 312 may be used to grab a flange at the top of an article 316 such as FOUP. The article 316 may be transported to a predetermined place, such as the load port of a particular processing apparatus, by controlling the movement of the overhead traveling vehicle 100. Once the article 316 reaches the place over the load port of the particular processing apparatus, the elevation platform 312 may be lowered until the article 316 is placed on the load port, and then the semiconductor wafers stored in the article 316 may be taken out and processed by the corresponding processing apparatus.

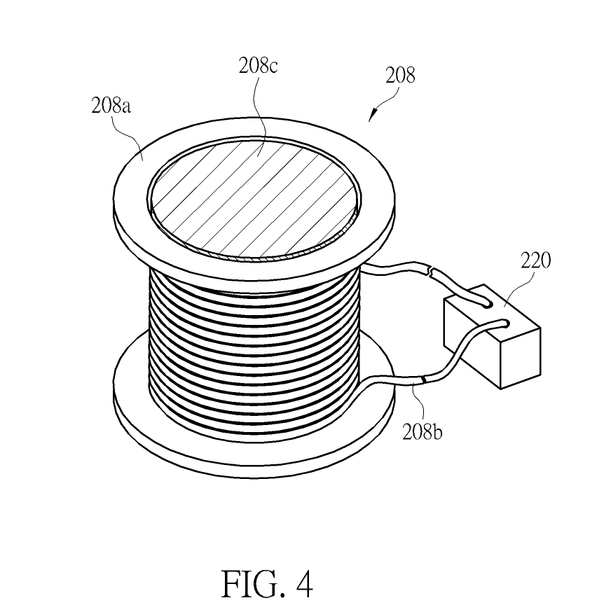

FIG. 4 illustrates in greater detail an exemplary magnetic field generation unit installed in an overhead traveling vehicle in accordance with one embodiment of the present invention. As shown in FIG. 4, the magnetic field generation unit 208 installed in the mobile drive unit 200 is a solenoid, also called electromagnet, consisting of a hollow chamber 208a, a number of turns of wire 208b wound around the peripheral of the hollow chamber 208a, and an optional magnetic core 208c disposed in the cavity of the hollow chamber 208a. The ends of the wire 208b may be electrically connected to a battery 220 which is utilized to generate an electric potential difference between the ends of the wire 208b. By controlling the amount of electric current in the wire 208b, the magnetic field as well as the magnetic force generated by the magnetic field generation unit 208 may be changed. In this way, the mobile drive unit 200 equipped with the magnetic field generation unit 208 is capable of attracting any magnetized object. Besides, the magnetic core 208c may be made from a ferromagnetic or ferromagnetic material, which is able to concentrate the magnetic flux and therefore generate stronger magnetic field. Although the magnetic field generation unit 208 disclosed above includes a number of turns of wire 208b and the magnetic core 208c, the magnetic core 208c of the solenoid 208 may be omitted in accordance with another embodiment of the present invention. That is to say, the magnetic core 208c is an optional component of the solenoid 208. Besides, the structure of the magnetic field generation unit 306 of the hoist unit 300 shown in FIG. 3 may be the same as the structure of the magnetic field generation unit 208 shown in FIG. 4. That is to say, the magnetic field generation unit 306 of the hoist unit 300 may also be the solenoid including the hollow chamber, the wire, and the optional magnetic core.

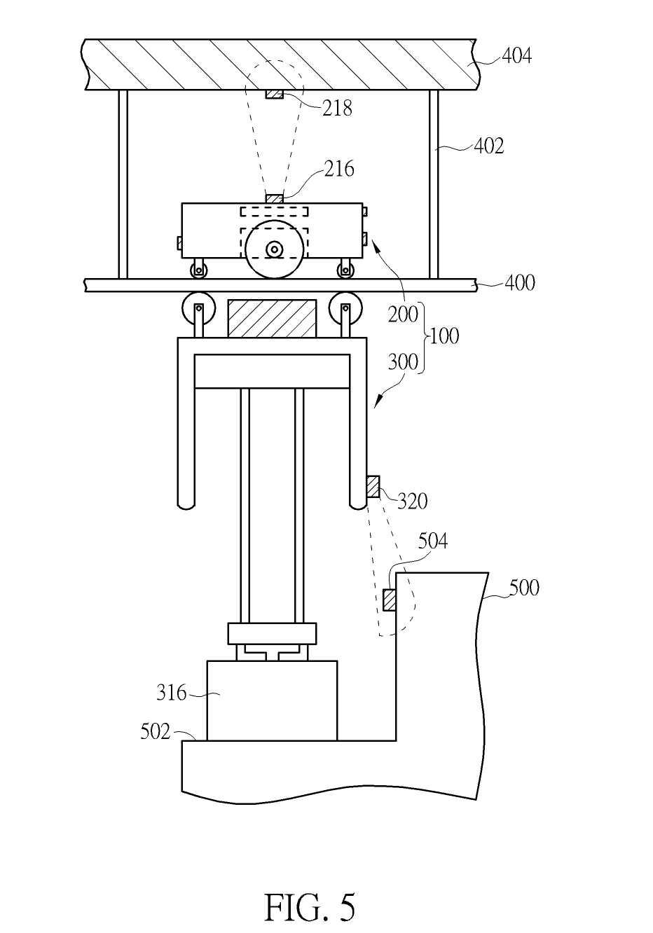

FIG. 5 illustrates an exemplary operation of an overhead traveling vehicle while lifting or lowering a container configured to be loaded with wafers in accordance with one embodiment of the present invention. During the operation, the mobile drive unit 200 as well as the hoist unit 300 may move along a predetermined route until a predetermined destination is reached. At this time, the location of the overhead traveling vehicle 100 can be determined by the aid of the location sensor 216 and the fiducial mark 218. Besides, in order to let the article 316 be accurately placed on the load port 502 of the processing apparatus, the location of the overhead traveling vehicle 100 may be further adjusted based on location information transmitted from the location sensor 320 of the hoist unit 300. For instance, the location sensor 320 may detect the location of an identification signal transmitter 504 attached to the processing apparatus 500. In one case, if the distance between the location sensor 320 and the identification signal transmitter 504 is less than or equal to a predetermined threshold, the article 316 will be lowered until it reaches the load port 502 of the processing apparatus 500. In another case, if the distance between the location sensor 320 and the identification signal transmitter 504 is greater than a predetermined threshold, the overhead traveling vehicle 100 will slightly move away from its original location until the distance between the location sensor 320 and the identification signal transmitter 504 is less than or equal to a predetermined threshold. Accordingly, since the overhead traveling vehicle 100 is not guided by any rail during the transportation, the overhead traveling vehicle 100 can move on the platform 400 in a more free and flexible way compared with conventional rail-guided transportation system.

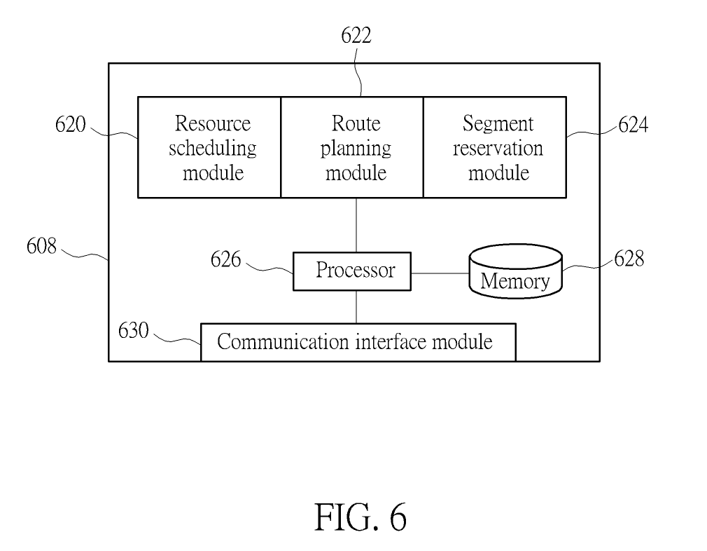

FIG. 6 illustrates in great detail the components of an exemplary management module that may be utilized to control the movement of an overhead traveling vehicle in accordance with one embodiment of the present invention. The management module 608 according to one embodiment of the structure shown in FIG. 6 is operable to generate commands to the corresponding overhead traveling vehicle 100. Once the overhead traveling vehicle 100 receives the commands transmitted from the management module 608, it can perform the assigned task of the received commands.

Specifically, the management module 608 may include a resource scheduling module 620, a route planning module 622, a segment reservation module 624, a communication interface module 630, a processor 626, and a memory 628. Management module 608 may represent a single component, multiple components located at a central location within the workplace, or multiple components distributed throughout the workplace. For example, the management module 608 may be capable of communicating information between the mobile drive units 200 and coordinating the movement of mobile drive units 200 within workplace 70. In general, management module 608 may include any appropriate combination of hardware and/or software suitable to provide the described functionality.

The processor 626 is operable to execute instructions associated with the functionality provided by management module 608. The processor 626 may include one or more general purpose computers, microprocessors, or other processing devices capable of communicating electronic information. Examples of processor 626 include one or more application-specific integrated circuits (ASICs), field-programmable gate arrays (FPGAs), digital signal processors (DSPs) and any other suitable specific or general purpose processors.

The memory 628 stores processor instructions, request or reservation information, state information for the various components of transportation system and/or any other appropriate values, parameters, or information utilized by management module 608 during operation. The memory 628 may represent any collection and arrangement of volatile or non-volatile, local or remote devices suitable for storing data. Examples of memory 628 include, but are not limited to, random access memory (RAM) devices, read only memory (ROM) devices, magnetic storage devices, optical storage devices, or any other suitable data storage devices.

The resource scheduling module 620 processes received requests and generates one or more assigned tasks to be completed by the components of transportation system. Resource scheduling module 620 may also select one or more appropriate components for completing the assigned tasks and, using communication interface module 630, communicate the assigned tasks to the relevant components. Additionally, resource scheduling module 620 may also be responsible for generating assigned tasks associated with various management operations, such as prompting mobile drive units 200 to recharge batteries or have batteries replaced, instructing inactive mobile drive units 200 to park in a location outside the anticipated traffic flow or a location near the anticipated site of future tasks, and/or directing mobile drive units 200 selected for repair or maintenance to move towards a designated maintenance station.

The route planning module 622 receives route requests from mobile drive units 200. These route requests identify one or more destinations associated with a task the requesting mobile drive unit 20 is executing. In response to receiving a route request, the route planning module 622 generates a path to one or more destinations identified in the route request. The route planning module 622 may implement any appropriate algorithms utilizing any appropriate parameters, factors, and/or considerations to determine the appropriate path. After generating an appropriate path, the route planning module 622 transmits a route response identifying the generated path to the requesting mobile drive unit 20 using communication interface module 630.

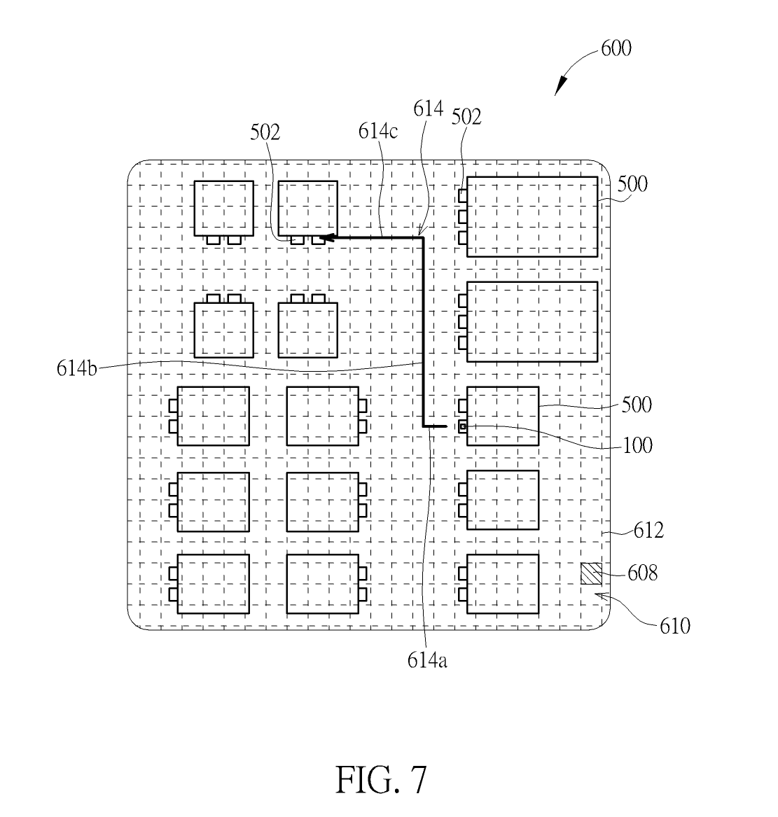

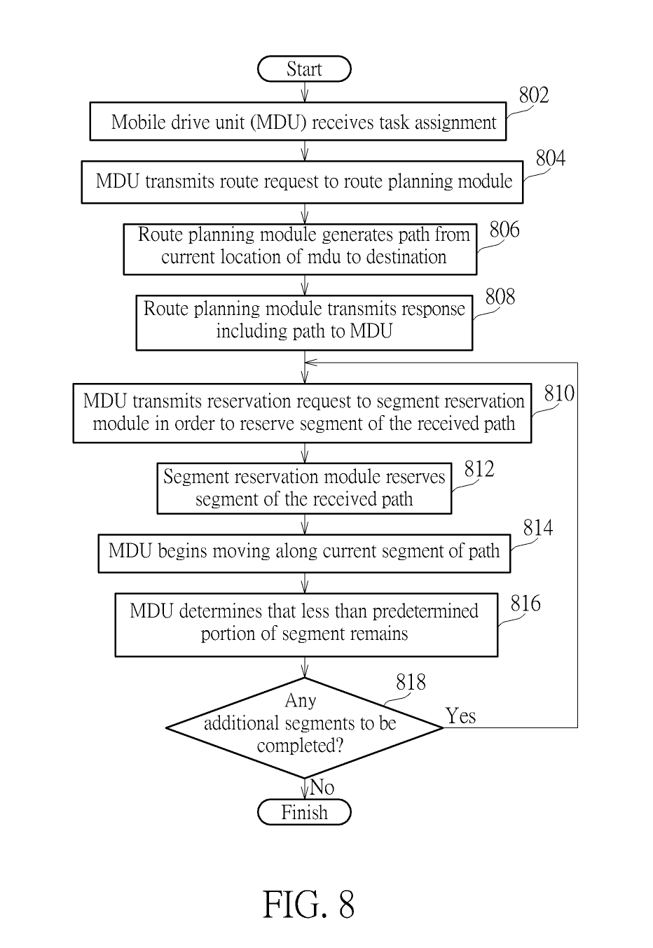

The segment reservation module 624 receives reservation requests from the mobile drive units 200 attempting to move along predetermined paths generated by the route planning module 622. These reservation requests request the use of a particular portion of workplace (referred to herein as a “segment”) to allow the requesting mobile drive unit 200 to avoid collisions with other mobile drive units 200 while moving across the reserved segment. In response to received reservation requests, the segment reservation module 624 transmits a reservation response granting or denying the reservation request to the requesting mobile drive unit 200 using the communication interface module 630. This process is discussed in greater detail below with respect to FIGS. 7 and 8.

The communication interface module 630 facilitates communication between the management module 608 and other components of transportation system 10, including reservation responses, reservation requests, route requests, route responses, and task assignments. These reservation responses, reservation requests, route requests, route responses, and task assignments may represent communication of any form appropriate based on the capabilities of the management module 608 and may include any suitable information. Depending on the configuration of the management module 608, the communication interface module 630 may be responsible for facilitating either or both of wired and wireless communication between the management module 608 and the various components of transportation system. In particular embodiments, the management module 608 may communicate using communication protocols such as 802.11, Bluetooth, or Infrared Data Association (IrDA) standards.

In general, the resource scheduling module 620, the route planning module 622, the segment reservation module 624, and the communication interface module 630 may each represent any appropriate hardware and/or software suitable to provide the described functionality. In addition, as noted above, the management module 608 may, in particular embodiments, represent multiple different discrete components, and any or all of the resource scheduling module 620, the route planning module 622, the segment reservation module 624, and the communication interface module 630 may represent components physically separated from the remaining elements of the management module 608. Moreover, any two or more of the resource scheduling module 620, the route planning module 622, the segment reservation module 624, and the communication interface module 630 may share common components. For example, in particular embodiments, the resource scheduling module 620, the route planning module 622, the segment reservation module 624 represent computer processes executing on the processor 626, and the communication interface module 630 includes a wireless transmitter, a wireless receiver, and a related computer process executing on the processor 626.

FIG. 7 illustrates an exemplary operation of an overhead traveling vehicle while transporting a container configured to be loaded with wafers in accordance with one embodiment of the present invention. FIG. 8 is a flowchart detailing an exemplary operation of a management module in managing the movement of an overhead traveling vehicle in accordance with one embodiment of the present invention. Any of the steps illustrated in FIG. 8 may be combined, modified, or deleted where appropriate, and additional steps may also be added to those shown in the flowchart. Moreover, the described steps may be performed in any suitable order without departing from the scope of the invention.

Referring to FIG. 7, in the illustrated embodiment of a transportation system, the workplace 600 is associated with a grid 610 comprising a plurality of cells 612, and at least one of the overhead traveling vehicles 100 is configured to move within workplace 600 by navigating from the center of one cell 14 to the center of another. Nonetheless, in alternative embodiments, the overhead traveling vehicle 100 may be configured to navigate grid 610 in any appropriate manner, and starting points, destinations, and any intermediate points on the predetermined path traversed by the overhead traveling vehicle 100 may or may not represent the center point of the cell 612 or any other portion of the grid 610. Furthermore, although FIG. 7 illustrates a grid-based embodiment of the transportation system, alternative embodiments of transportation system may utilize a gridless workplace having an arbitrary shape and structure.

Referring to FIGS. 7 and 8, the routing process begins at step 802 in which a task assignment is transmitted from the management module 15 and received by the mobile drive unit 200. The task assignment identifies one or more destinations associated with a corresponding task, and may identify the relevant destinations directly or by reference to the known location of specific components or a particular portion of workplace 600. The task assignment may also include any additional information suitable for the mobile drive unit 200 in completing the assigned task.

Upon receiving the task assignment, the mobile drive unit 200 requests a path to the location identified by the task assignment or, if the task assignment identifies multiple locations, to the first location identified by the task assignment. In the illustrated embodiment, at step 804, the mobile drive unit 200 requests a path by transmitting a route request to the route planning module 622. In particular embodiments, the route request may include one or more destination locations and the current location of the mobile drive unit 200 or the anticipated location of the mobile drive unit 200 when it completes its current segments 614a, 614b and 614c.

At step 806, when the route planning module 622 receives the route request, the route planning module 622 generates a path 614 starting from the current location of the requesting mobile drive unit 200 to the requested destination. As noted above, the route planning module 622 may use any suitable techniques to generate, select, or determine an appropriate path 614 for the requesting mobile drive unit 200. At step 808, the route planning module 622 may then communicate information identifying path 614 to the requesting mobile drive unit 200 as part of a route response.

After the route planning module 622 transmits information identifying the predetermined path 164, this information is received by the mobile drive unit 200. In particular embodiments, the mobile drive unit 20 may then store this information for subsequent use in navigating to the destination location. The mobile drive unit 200 then attempts to reserve a segment 164a or other suitable portions of the path 614. In the illustrated embodiment, at step 810, the mobile drive unit 200 reserves segment 614a by transmitting a reservation request to the segment reservation module 624. The reservation request identifies the segment 614a that mobile drive unit 200 is attempting to reserve. The reservation request may identify the relevant segment 164a in any manner appropriate based on the configuration and capabilities of mobile drive unit 200 and segment reservation module 624. For example, in particular embodiments, the reservation request identifies the relevant segments by identifying the starting and ending coordinates of that segment, by specifying a direction and distance from the current location of the mobile drive unit 200, or by including any other suitable information from which the requested segment can be identified, either independently or based on other information maintained by the segment reservation module 624 during operation.

The segment reservation module 624 receives the reservation request and extracts information identifying the requested segment from reservation request. The segment reservation module 624 then determines whether or not the requesting mobile drive unit 200 can reserve the requested segment.

Upon receiving reservation request, the segment reservation module 624 attempts to reserve the requested segment for mobile drive unit 200 at step 812. In particular embodiments, the segment reservation module 624 may modify the requested segment to account for potential uncertainties or errors in the calculated position of the mobile drive unit 200. For example, segment reservation module 624 may, under appropriate circumstances, expand, translate, and/or otherwise modify the requested segment to create a modified segment more suitable for use by the requesting mobile drive unit 200. The segment reservation module 624 may then notify mobile drive unit 200 of whether or not the mobile drive unit 200 has successfully reserved the segment for mobile drive unit 200. In particular embodiments, the segment reservation module 624 notifies mobile drive unit 200 by transmitting a reservation response to the mobile drive unit 200.

Once mobile drive unit 200 receives the reservation response from the segment reservation module 624, the mobile drive unit 200 begins moving away from its original location along the initial segment 614a of the path at step 814. At step 816, the mobile drive unit 200 determines that there is less than a predetermined portion of the initial segment 614a left to complete. As a result, the mobile drive unit 200 determines, at step 818, whether any additional segments remain to be completed in the current path 614.

If segments 814b and 814c remain to be completed in the current path 614, the mobile drive unit 200 attempts to reserve the next segment 614b, returning to step 810. If the mobile drive unit 200 reaches the end of the initial segment 614a before successfully reserving the next segment, the mobile drive unit 200 may stop its movement at the end of the initial segment 614a and remain stationary until mobile drive unit 200 successfully reserves the next segment 614b or obtains an alternative path. If no segments remain to be completed in the current path 614, the mobile drive unit 200 may notify the resource scheduling module 620 that the mobile drive unit 200 has completed its current task.

Since rails are not necessary components for the operation of the overhead traveling vehicle 100 and the mobile drive unit 200, the container 316 configured to be loaded with semiconductor wafers can be transported between the processing apparatus 500 in a more flexible and time-efficient way compared with conventional railed-guided system. Additionally, no rail needs to be added or removed during the process of adding or removing the processing equipment 500 into or out of the semiconductor foundry. Accordingly, during the renewal process, the processing equipment 500 other than the newly added or removed processing equipment 500 can still operate normally and the production rate of the semiconductor devices is not significantly affected.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An overhead traveling vehicle configured to transport wafers, comprising:
a mobile drive unit configured to move along a predetermined route on a first side of a platform hung on a ceiling, wherein the mobile drive unit comprises a first magnet; and
a hoist unit configured to move along the predetermined route according to a position of the mobile drive unit, wherein the hoist unit comprises a second magnet and is configured to be hung on a second side of the platform by a magnetic force between the first magnet and the second magnet.

2. The overhead traveling vehicle of claim 1, wherein the mobile drive unit further comprises:
a body, wherein the first magnet is attached to the body; and
at least a pair of motorized wheels connected to the body.

3. The overhead traveling vehicle of claim 1, wherein the hoist unit further comprises:
a body, wherein the second magnet is attached to the body; and
at least a pair of motorized wheels connected to the body.

4. The overhead traveling vehicle of claim 1, wherein the first magnet and the second magnet are permanent magnets or temporary magnets.

5. The overhead traveling vehicle of claim 4, wherein the temporary magnets are electromagnets.

6. The overhead traveling vehicle of claim 1, wherein each of the magnets comprises:
a magnetic core; and
a plurality of turns of wire wound around a peripheral of magnetic core, wherein two ends of the wire are electrically connected to at least a battery.

7. The overhead traveling vehicle of claim 1, wherein the mobile drive unit and the hoist unit are separated by the platform, and the mobile drive unit is not in direct contact with the hoist unit.

8. The overhead traveling vehicle of claim 1, wherein the hoist unit comprises an elevation platform configured to lift or lower an article.

9. The overhead traveling vehicle of claim 1, wherein the mobile drive unit further comprises at least an obstacle sensor configured to detect an obstacle in the proximity of the mobile drive unit.

10. The overhead traveling vehicle of claim 1, wherein the mobile drive unit further comprises at least a location sensor configured to determine the location of the mobile drive unit.

11. A method for operating an overhead traveling vehicle, comprising:
generating a predetermined route by a route planning module;
transmitting an information of the predetermined route to a mobile drive unit;
moving the mobile drive unit along the predetermined route on a first side of a ceiling, wherein the mobile drive unit comprises a first magnet; and
concurrently moving a hoist unit along the predetermined route according to a position of the mobile drive unit during the step of moving the mobile drive unit, wherein the hoist unit comprises a second magnet and is configured to be hung on a second side of the ceiling by a magnetic force between the first magnet and the second magnet.

12. The method of claim 11, wherein the mobile drive unit further comprises:
a body, wherein the first magnet is attached to the body; and
at least a pair of motorized wheels connected to the body.

13. The method of claim 11, wherein the hoist unit further comprises:
a body, wherein the second magnet is attached to the body; and
at least a pair of motorized wheels connected to the body.

14. The method of claim 11, wherein the first magnet and the second magnet are permanent magnets or temporary magnets.

15. The method of claim 14, wherein the temporary magnets are electromagnets.

16. The method of claim 15, wherein each of the electromagnets comprises:
a magnetic core; and
a plurality of turns of wire wound around a peripheral of magnetic core, wherein two ends of the wire are electrically connected to at least a battery configured to supply electric current through the wire.

17. The method of claim 11, wherein the mobile drive unit and the hoist unit are separated by the ceiling.

18. The method of claim 11, further comprising detecting an obstacle in the proximity of the mobile drive unit by at least an obstacle sensor of the mobile drive unit.

19. The method of claim 11, further comprising determining a location of the mobile drive unit by at least a location sensor of the mobile drive unit.

20. The method of claim 11, wherein the platform is configured to comprise a plurality of cells, and the method further comprises moving the mobile drive unit over centers of portions of the cells.

21. The method of claim 11, wherein the predetermined route is generated based on a current position of the mobile drive unit and a destination of the mobile drive unit.

22. The method of claim 11, wherein the hoist unit is configured to transport a plurality of wafers among a plurality of processing apparatuses.

23. A system for operating an overhead traveling vehicle, comprising:
means for generating a predetermined route;
means for transmitting an information of the predetermined route; and
at least an overhead traveling vehicle operable to receive the information of the predetermined route, wherein the overhead traveling vehicle comprises:
a mobile drive unit configured to move along the predetermined route on one side of a ceiling, wherein the mobile drive unit comprises a magnetic field generation unit; and
a hoist unit configured to move along the predetermined route according to a position of the mobile drive unit, wherein the hoist unit comprises a further magnetic field generation unit and is configured to be hung on another side of the ceiling by a magnetic force between the magnetic field generation unit and the further magnetic field generation unit.
